(19) United States
(12) Patent Application Publication
(10) Pub. No.: US 2011/0273827 A1
(43) Pub. Date: Nov. 10, 2011

(54) VIBRATION-DAMPING CONTAINING CASE FOR ELECTRONIC DEVICE, THE ELECTRONIC DEVICE, AND ELECTRONIC APPARATUS HAVING THE ELECTRONIC DEVICE MOUNTED THEREON

(76) Inventors: Shigeru Kasai, Tokyo (JP); Hiroshi Sakai, Tokyo (JP); Yashuiro Sasaki, Tokyo (JP)

(21) Appl. No.: 13/145,139

(22) PCT Filed: Jan. 25, 2010
(86) PCT No.: PCT/JP2010/000397

§ 371 Date: Jul. 19, 2011

(30) Foreign Application Priority Data
Jan. 30, 2009 (JP) 2009-020946

(51) Int. Cl. H05K 5/00

(52) U.S. Cl. 361/679.01

(57) ABSTRACT

A vibration-damping containing case for an electronic device of the present invention includes a stepped projection which is provided on an inner surface of a case member containing an electronic device which becomes a vibration source in a state of covering an outer surface of the electronic device, and which holds the outer surface of the electronic device in a state of sandwiching the outer surface of the electronic device, and the stepped projection holds the outer surface of the electronic device via a vibration-damping member.

### TECHNICAL FIELD

This invention relates to a vibration-damping containing case for an electronic device, the electronic device, and an electronic apparatus having the electronic device mounted thereon. In particular, this invention relates to a vibration-damping containing case for an electronic device that can suppress the vibrations of the device housed in it from being transmitted to the outside, and the electronic device, and an electronic apparatus having the electronic device mounted thereon.

### BACKGROUND ART

In general, an electronic device having an actuator that acts mechanically, involves vibration. In particular, there is a case where an electronic device in which an actuator operates at high speed, becomes a vibration source, and the vibrations are transmitted to the outside. Furthermore, there is also a case where the vibrations become a cause of noise.

For example, in recent years, as digital information communication technology has been developed, broadband services that distribute high content volumes have spread and become popular, enabling users to enjoy animation and music. Accompanying this, the amount of information handled by electronic apparatuses such as personal computers has been increasing. For this reason, electronic apparatuses require high performance central processing units, image processing devices, communication devices, and the like which perform information processing of large volumes of data, as well as high density, large volume, and high speed memory devices such as hard disc drives. In order to make the usage of personal computers comfortable, high speed transfer to main memory, high speed writing when downloading content, and the like, are required. Therefore, demand for high speed memory devices is especially great. In order to realize a high speed memory device, it is effective to rotate a data recording medium at high speed and to operate an arm that moves a magnetic head that reads stored data from the medium and writes data to the medium, at high speed.

In other words, in order to perform high-speed rotation of the medium in the memory device and high-speed operation of the arm, it is necessary to operate the mechanism elements at higher speed, and change the location of the mechanism elements at high speed. Accompanying high-speed operation of the mechanism elements and the like, mechanical vibration occurs, and furthermore, sound waves caused by the vibration occur, making the noise of the memory device greater.

As a result, in Patent Document 1, as shown in FIG. 13, it is proposed that a damping plate 102 is adhered on a top plate member 101 of a case 100 that contains a memory device (electronic device), using double sided tape 103. Using this construction, a space of 100 μm or greater is formed between the top plate member 101 and the damping plate 102, and the sound pressure radiated from the top plate member 101 is decreased while passing through the space, so that the noise is attenuated. It is reported that the transmission loss of the sound pressure can be increased as the area ratio of the damping plate 102 with respect to the top plate member 101 is increased.

In Patent Document 2, as shown in FIG. 14, it is proposed that a top plate member 111 of a case 110 that contains a memory device (electronic device), is drawn to form multiple beads 112 provided in a rib shape. Using this construction, it is possible to improve the mechanical stiffness of the top plate member 111, suppressing the vibrations, so that it is possible to attenuate the noise occurring. It is reported that it is effective to form the beads 112 such that they pass through the area at the center of the vibrations.

### PRIOR ART DOCUMENTS

### Patent Documents

[Patent Document 1] Japanese Unexamined Patent Application, First Publication No. 1999-328946
[Patent Document 2] Japanese Unexamined Patent Application, First Publication No. 2002-015557

### SUMMARY OF THE INVENTION

### Problem to be Solved by the Invention

However, in both of the Patent Documents 1 and 2, the memory device is fixed directly to the electronic apparatus. Therefore, mechanical vibration of a mechanism that causes high speed operation of a motor or arm for a high speed rotating medium, is transmitted unchanged, vibrating the whole unit, and thereby generating noise. As a result, even if spaces are formed in the top plate members 101 and 111, or the stiffness is increased, they vibrate together, and also vibrate (generate sound waves in) the electronic apparatus, which has a larger housing than the memory device, so in practice the noise is not attenuated.

This invention has been made in view of the above circumstances, with an exemplary object of providing a vibration-damping containing case for an electronic device, this electronic device, and an electronic apparatus having this electronic device mounted thereon, which realizes a small sized electronic device with excellent low noise characteristics by improving the damping and sound insulation in the electronic device in which a vibration source such as a memory device is mounted, using a simple construction.

### Means for Solving the Problem

A vibration-damping containing case for an electronic device of the present invention includes a stepped projection which is provided on an inner surface of a case member containing an electronic device which becomes a vibration source in a state of covering an outer surface of the electronic device, and which holds the outer surface of the electronic device in a state of sandwiching the outer surface of the electronic device, and the stepped projection holds the outer surface of the electronic device via a vibration-damping member.

### Effect of the Invention

According to the construction of this invention, it is possible to limit the transmission of vibrations by intervening the vibration-damping member between the stepped projection of the case member which holds the electronic device so as to sandwich it, and the electronic device, so that it is possible to prevent the vibrations being transmitted to the outside. Moreover, the case member can shield the sound waves generated and limit the transmission of noise by covering the whole of the electronic device. Consequently, it is possible to improve the damping and the sound insulation of the electronic device, which is a vibration source, using a simple construction, so that it is possible to realize a small sized electronic device with excellent low noise characteristics.

### BRIEF DESCRIPTION OF THE DRAWINGS

FIG. 1 is a perspective view showing the appearance of an electronic device of a first exemplary embodiment of this invention.

FIG. 2 is an exploded perspective view showing the structure of the electronic device shown in FIG. 1.

FIG. 3 is a cross-sectional view along line A-A of FIG. 1, and shows the structure of a vibration-damping containing case of the electronic device shown in FIG. 1.

FIG. 4 is a cross-sectional view along line B-B of FIG. 1, and shows the structure of the vibration-damping containing case of the electronic device shown in FIG. 1.

FIG. 5 is an enlarged longitudinal sectional view showing the structure of main parts that secure the vibration-damping containing case shown in FIG. 1.

FIG. 6 is an enlarged longitudinal sectional view showing the structure of main parts that secure the vibration-damping containing case shown in FIG. 1, which are different from the parts shown in FIG. 5.

FIG. 7 is a table showing test results, which are the effects obtained by using the vibration-damping containing case according to the first example.

FIG. 8 is a cross-sectional view corresponding to line A-A of FIG. 1, and shows the structure of a vibration-damping containing case for an electronic device of a second exemplary embodiment of this invention.

FIG. 9 is a cross-sectional view corresponding to line B-B of FIG. 1, and shows the structure of the vibration-damping containing case for the electronic device shown in FIG. 8.

FIG. 10 is a cross-sectional view corresponding to line A-A of FIG. 1, and shows the structure of a vibration-damping containing case for an electronic device of a third exemplary embodiment of this invention.

FIG. 11 is a cross-sectional diagram corresponding to line B-B of FIG. 1, and shows the structure of the vibration-damping containing case for the electronic device shown in FIG. 10.

FIG. 12 is a perspective view showing the appearance of the structure of a vibration-damping containing case for an electronic device of a fourth exemplary embodiment of this invention.

FIG. 13 is a diagram showing the structure of a vibration-damping containing case for an electronic device in a related art of this invention.

FIG. 14 is a diagram showing the structure of a vibration-damping containing case for an electronic device, which is different from the vibration-damping containing case for an electronic device shown in FIG. 13 of a related art of this invention.

### EXEMPLARY EMBODIMENTS FOR CARRYING OUT THE INVENTION

A stepped projection is provided on an inner surface of a case member containing an electronic device which becomes a vibration source in a state of covering an outer surface of the electronic device, and holds the outer surface of the electronic device in a state of sandwiching the outer surface of the electronic device. The stepped projection holds the outer surface of the electronic device via a vibration-damping member. The stepped projection is formed so as to extend in a crosswise direction or a lengthwise direction of the case member. Furthermore, a plurality of the stepped projections are formed on at least each of opposing surfaces facing each other among inner surfaces of the case facing the outer surface of the electronic device, so as to parallel to each other. Hereunder is a detailed description of exemplary embodiments of this invention with reference to the drawings.

### Exemplary Embodiment 1

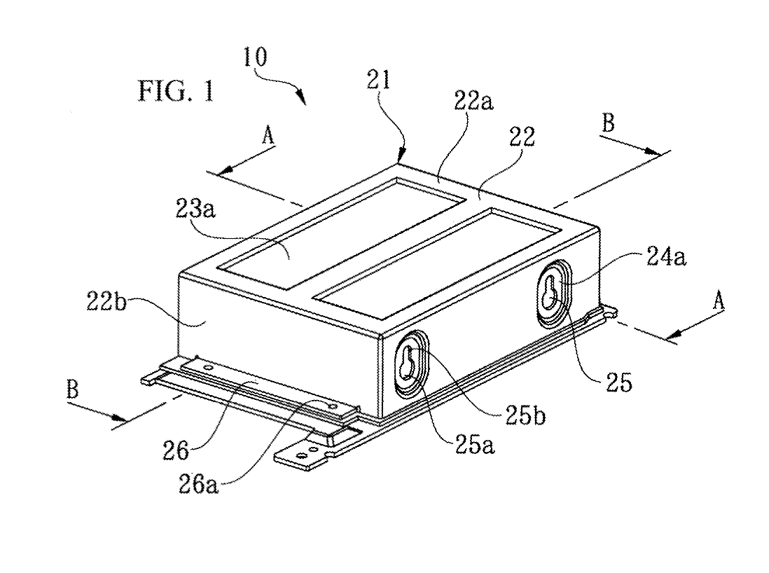

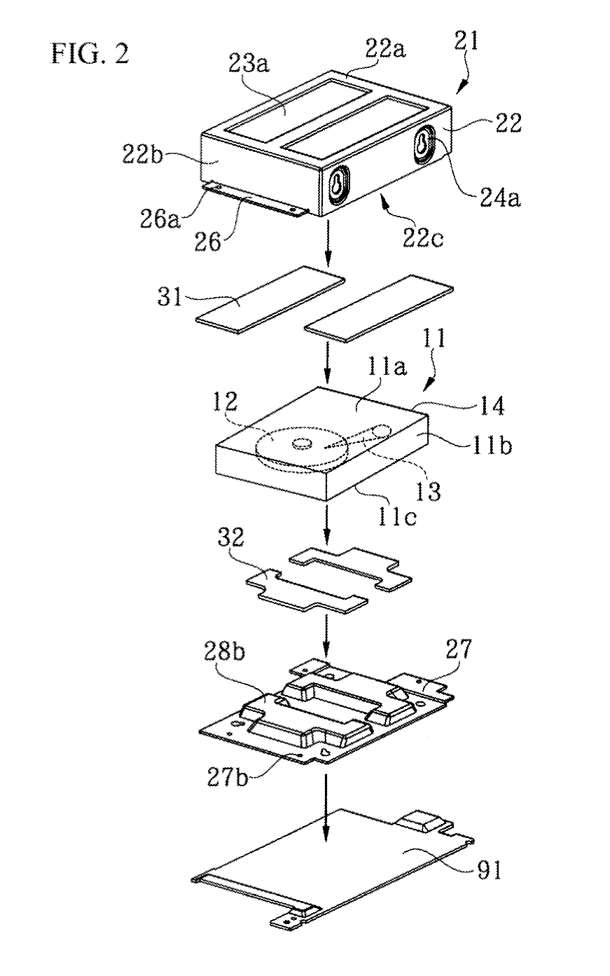

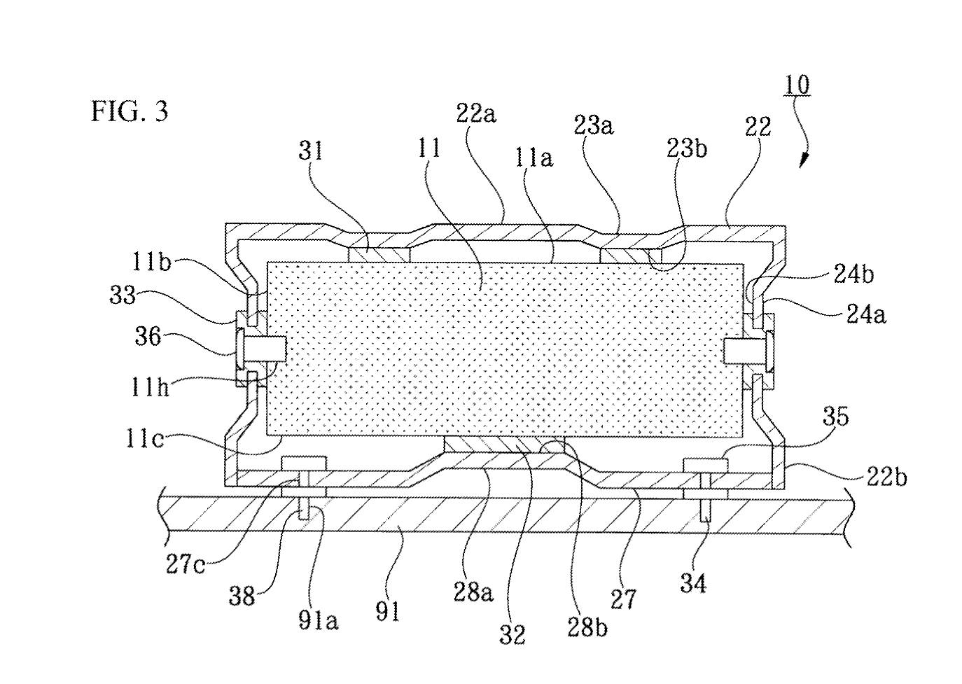

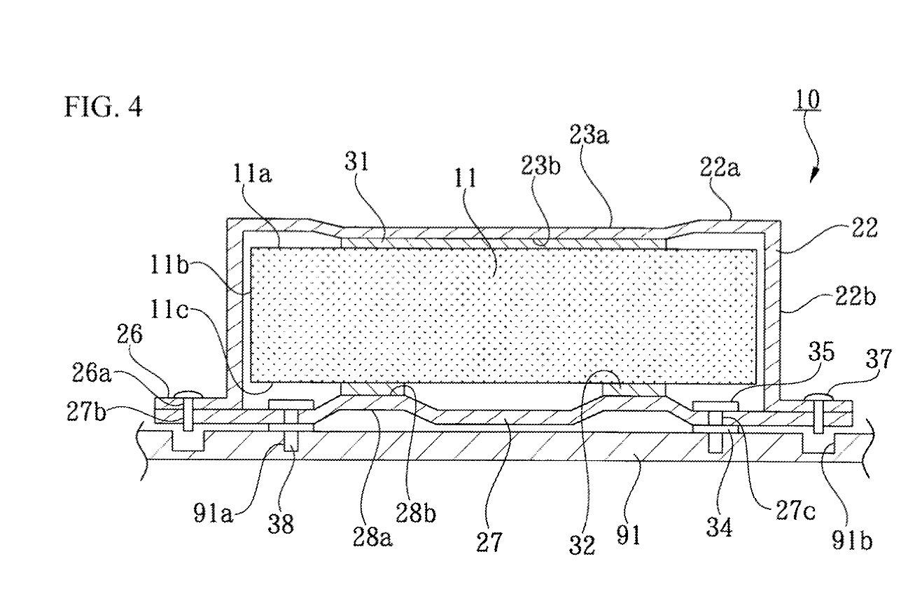

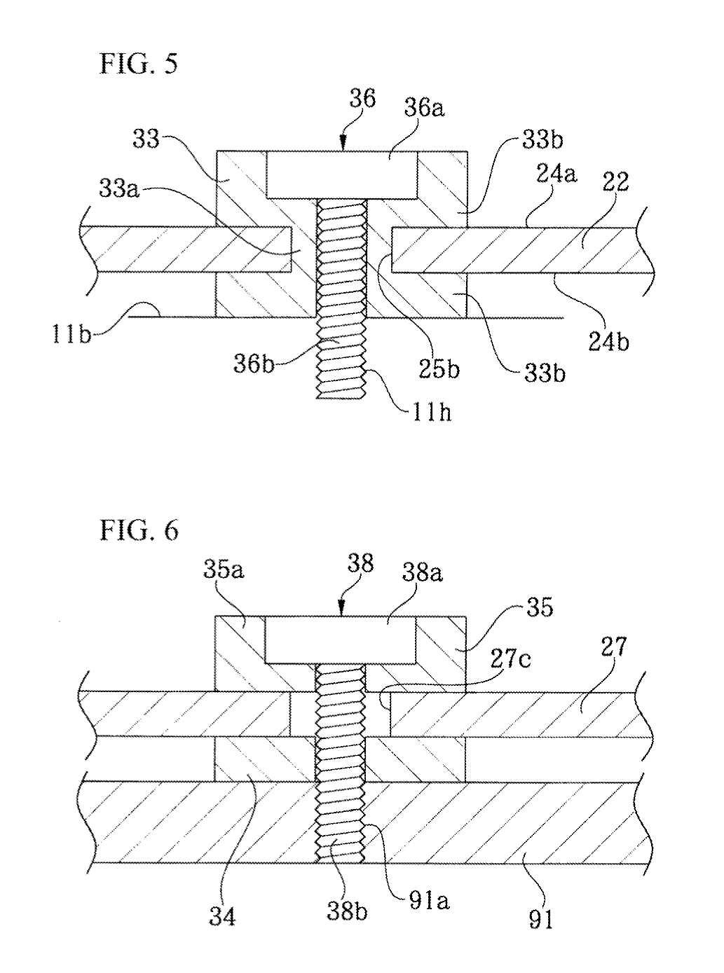

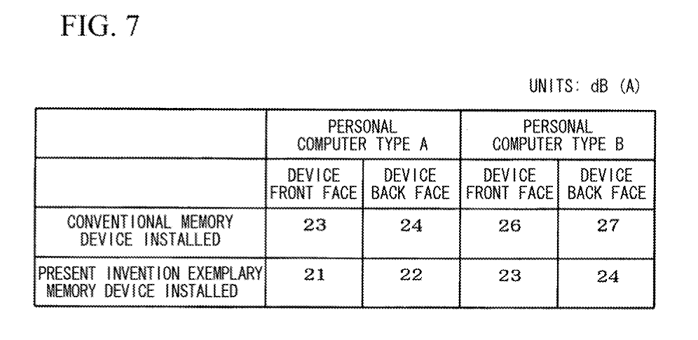

FIG. 1 is a perspective view showing the appearance of an electronic device of a first exemplary embodiment of this invention. FIG. 2 is an exploded perspective view showing the structure of the electronic device shown in FIG. 1. FIG. 3 is a cross-sectional view along line A-A of FIG. 1, and shows the structure of a vibration-damping containing case of the electronic device shown in FIG. 1. FIG. 4 is a cross-sectional view along line B-B of FIG. 1, and shows the structure of the vibration-damping containing case of the electronic device shown in FIG. 1. FIG. 5 is an enlarged longitudinal sectional view showing the structure of main parts that secure the vibration-damping containing case shown in FIG. 1. FIG. 6 is an enlarged longitudinal sectional view showing the structure of main parts that secure the vibration-damping containing case shown in FIG. 1, which are different from the parts shown in FIG. 5. FIG. 7 is a table showing test results, which are the effects obtained by using the vibration-damping containing case according to the first example.

As shown in FIG. 1, a shielded memory device 10 is produced, and it contains a memory body section 11, as shown in FIG. 2, in a rectangular vibration-damping containing case 21. The memory device 10 is mounted on a housing 91 (refer to FIG. 2 to FIG. 4) of an electronic apparatus such as a personal computer, for example. The memory body section 11 of the memory device 10 is constructed as a hard disc drive in which a data recording medium 12 and an arm 13 are incorporated in an outer member 14. The medium 12 is rotated at high speed by a motor, which is not shown in the drawing. The arm 13 supports a magnetic head for reading from and writing to the medium 12, and operates at high-speed. As a result, the memory body section 11 becomes a source of vibration, which generates mechanical vibration accompanying the high-speed operation of the medium 12 and the arm 13, and generates sound waves caused by the vibration, so that it becomes a source of noise in the electronic apparatus.

The vibration-damping containing case 21 includes a vibration-damping cover 22 and a vibration-damping plate 27 as shown in FIG. 2. The vibration-damping cover 22 faces the top face 11a and the side faces 11b on the top cover side of the memory body section 11. The vibration-damping plate 27 faces the bottom face 11c of the memory body section 11 which is secured on the housing (base) 91 side of the electronic apparatus. The vibration-damping containing case 21 encloses the memory body section 11 so as to cover the whole memory body section 11, by containing the memory body section 11 from the opening 22c of the vibration-damping cover 22, and covering it with the vibration-damping plate 27. The vibration-damping cover 22 and the vibration-damping plate 27 are fabricated from metal material.

Concave parts 23a are formed in the vibration-damping cover 22 in two parallel lines as shown in FIG. 3 and FIG. 4. The concave parts 23a are rectangular, and are indented in a concave shape inwardly from the outer surface of the top face part 22a, and extend in the long direction (lengthwise direction). The concave parts 23a are formed in a regular rectangular shape matching the shape of the top face 11a of the memory body section 11, using oblong or circular drawing. The concave parts 23a of the vibration-damping cover 22 are indented from the outer surface of the top face part 22a toward the inner surface. As a result, stepped projections 23b are formed on the inner surface of the vibration-damping cover 22, which protrude in a convex shape toward the top face 11a of the memory body section 11. The stepped projections 23b are clamped to the top face 11a of the memory body section 11 via intervening vibration-damping members 31. The vibration-damping members 31 are adhered to the stepped projections 23b and the top face 11a of the memory body section 11 by double-sided tape or adhesive. The vibration-damping members 31 are formed in a similar shape to the clamping faces of the stepped projections 23b that clamp to the top face 11a of the memory body section 11. The vibration-damping members 31 are fabricated mainly from organic material, for example rubber material, which has elasticity as well as a vibration suppressing function that damps vibration and limits its transmission. Here, the stepped projections conceptually include a convex part having a flat tip face.

Similarly, concave parts 28a are formed in the vibration-damping plate 27 in two parallel rows as shown in FIG. 3 and FIG. 4. The concave parts 28a are indented in a concave shape inwardly from the outer surface and extend in the short direction (crosswise direction). The concave parts 28a are formed in an irregular rectangular shape matching the shape of the bottom face 11c of the memory body section 11 using oblong or circular drawing. The concave parts 28a of the vibration-damping plate 27 are indented from the outer surface toward the inner surface. As a result, stepped projections 28b are formed on the inner surface of the vibration-damping plate 27, which protrude in a convex shape toward the bottom face 11c of the memory body section 11. The stepped projections 28b are clamped to the bottom face 11c of the memory body section 11 via intervening vibration-damping members 32. The vibration-damping members 32 are adhered to the stepped projections 28b and the bottom face 11c of the memory body section 11 by double-sided tape or adhesive. The vibration-damping members 32 are formed in a similar shape to the clamping faces of the stepped projections 28b that are clamped to the bottom face 11c of the memory body section 11. The vibration-damping members 32 are fabricated mainly from organic material, for example rubber material, which has elasticity as well as a vibration suppressing function that damps vibration and limits its transmission.

Concave parts 24a are provided in four places at opposite ends of two opposite faces of the side face parts 22b of the vibration-damping cover 22 such that they correspond to female threaded holes 11h to be screwed into, which are prepared in the side faces 11b of the memory body section 11. The concave parts 24a are approximately circular, and are indented inwardly from the lengthwise outer surface of the side face parts 22b. The concave parts 24a are formed by oblong or circular drawing. The concave parts 24a are indented in an ellipse, and screw holes 25 for screw fastening the memory body section 11 are formed in their centers. The screw holes 25 are formed such that slotted hole parts 25b continue to large diameter holes 25a. The concave parts 24a of the vibration-damping cover 22 are indented from the outer surfaces of the side face parts 22b to the inner surfaces. As a result, stepped projections 24b are formed on the inner surfaces of the vibration-damping cover 22, which protrude toward the side faces 11b of the memory body section 11. Male screws 36 are screwed together with the female threaded holes 11h of the side faces 11b of the memory body section 11. The stepped projections 24b are screwed to the memory body section 11 such that they are clamped to the side faces 11b of the memory body section 11 by the pressure of the tightening force of the male screws 36 via intervening vibration-damping members 33. A vibration-damping member 33, as shown in FIG. 5, is formed as a short cylinder such that a head 36a and an upper part of a screw part 36b of the male screw 36 that is screwed to the side face 11b of the memory body section 11 can be inserted. Flange parts 33h are formed at the two ends of a cylinder part 33a of the vibration-damping member 33, and project outwards in a disc shape. The cylinder part 33a of the vibration-damping member 33 is formed with an outer diameter approximately equal to the open width of the slotted hole part 25b of the screw hole 25 opening in the concave part 24a (stepped projection 24b) of the vibration-damping cover 22. The flange parts 33b of the vibration-damping member 33 are separated by a gap approximately equal to the thickness of the vibration-damping cover 22, and are formed with an outer diameter approximately equal to the diameter of the opening of the large diameter hole part 25a of the screw hole 25 opening in the concave part 24a (stepped projection 24b) of the vibration-damping cover 22. The vibration-damping members 33 are fabricated mainly from organic material, for example urethane material, which has elasticity as well as a vibration suppressing function that damps vibration and limits its transmission.

Flange parts 26 are formed on the vibration-damping cover 22, which project outwards from the periphery on the opening 22c side of the two side face parts 22b on the short sides. Screw holes 26a are formed at the two ends of the flange parts 26 such that the male screws 37 can pass therethrough.

Female threads 27b are formed in side edges of the vibration-damping plate 27 corresponding to the flange parts 26 of the vibration-damping cover 22, and are screwed together with the male screws 37 passing through the screw holes 26a, and clamp the vibration-damping cover 22 securely to the vibration-damping plate 27. Female threads 91a are formed in the housing 91 of the electronic apparatus, and by screwing male screws 38 into the female threads 91a, the vibration-damping plate 27 can be clamped and secured to the housing 91. Screw holes 27c are formed in the four corners inside of the female threads 27b in the vibration-damping plate 27, which correspond to the female threads 91a, and which open such that the male screws 38 can pass through. This vibration-damping plate 27 is screwed to the housing 91 so as to be clamped by the tightening force of the male screws 38 screwed into the female threads 91a of the housing 91 of the electronic apparatus via intervening vibration-damping members 34 and 35. The vibration-damping members 34 are formed in a regular washer shape through which the screw parts 38b of the male screws 38 can be passed as shown in FIG. 6. The vibration-damping members 35 are provided with a rib shape 35a around their apertured disc shaped periphery so as to be passed through by the screw parts 38b of the male screws 38 and surround the heads 38a. The vibration-damping members 34 and 35 are fabricated mainly from organic material, for example urethane material, which has elasticity as well as a vibration suppressing function that damps vibration and limits its transmission. Grooves 91b are formed in the housing 91 of the electronic apparatus such that the tip ends of the male screws 37 that screw the flange parts 26 of the vibration-damping cover 22 to the female threads 27b to clamp them securely, do not touch. The vibration-damping members 34 and 35 may be formed in a cylindrical shape with flanges similar to the vibration-damping members 33.

Using this construction, the memory device 10 can be assembled in the housing 91 of the electronic apparatus using the following procedure. Firstly, the vibration-damping plate 27, to whose stepped projections 28b the vibration-damping members 32 are adhered, is fastened securely to the housing 91 of the electronic apparatus by the male screws 38 via the vibration-damping members 34 and 35. Next, the memory body section 11 is installed in the vibration-damping cover 22, to whose stepped projections 23b the vibration-damping members 31 are adhered, through the opening 22c. Afterwards, the flange parts 33h of the vibration-damping members 33 are passed through the large diameter hole parts 25a of the screw holes 25 which opens in the stepped projections 24b of the vibration-damping cover 22, and the male screws 36 are positioned and screwed into the female threaded holes 11h of the memory body section 11 to fasten them temporarily during insertion of the cylindrical parts 33a into the slotted hole parts 25b. Next, the male screws 37 are passed through the screw holes 26a of the flange parts 26 of the vibration-damping cover 22, and screwed into the female threads 27b of the vibration-damping plate 27 to fasten them temporarily. After this, the male screws 36 and 37 are fastened securely to the female threaded holes 11h of the memory body section 11 and the female threads 27b of the vibration-damping plate 27 respectively. As a result, it is possible to clamp, fasten, and secure the vibration-damping cover 22 and the vibration-damping plate 27 to the memory body section 11 via the vibration-damping members 31 to 33, and fix them together mechanically. Simultaneously, it is possible to fasten the vibration-damping plate 27 securely to the housing 91 of the electronic apparatus via the vibration-damping members 34 and 35, and fix them together mechanically. Assembling the memory device 10 to the housing 91 of the electronic apparatus is not limited to the above-described procedure. For example, the memory body section 11 may be covered by the vibration-damping cover 22 in a state in which it is mounted on the stepped projections 28b of the vibration-damping plate 27, and the male screws 36 are screwed in.

In this state, the memory device 10 contains the memory body section 11 in a state in which it is secured and covered inside of the vibration-damping cover 22 and the vibration-damping plate 27. As a result, it is possible to shield the memory body section 11, being a source of noise, and ensure the sound insulation characteristics.

Furthermore, since a pair of concave parts 23a (stepped projections 23b) extends in parallel across the top face parts 22a of the vibration-damping cover 22, the stiffness of the vibration-damping cover 22 is enhanced. Furthermore, since a pair of concave parts 28a (stepped projections 28b) extends in parallel across the vibration-damping plate 27, the stiffness of the vibration-damping plate 27 is enhanced. Moreover, the vibration-damping cover 22 and the vibration-damping plate 27 are clamped to the outer member 14 (top face 11a and bottom face 11c) of the memory body section 11 in relative positions whereby the stepped projections 23b of the vibration-damping cover 22 and the stepped projections 28b of the vibration-damping plate 27 face each other and are perpendicular to each other. This construction further enhances the stiffness of the vibration-damping containing case 21. As a result, vibration of the vibration-damping containing case 21 can be suppressed even if vibration caused by the high-speed operation of the memory body section 11 contained therein is transmitted, so that the damping characteristics can be improved.

Furthermore, the vibration-damping members 31 intervene between the stepped projections 23b of the vibration-damping cover 22 and the memory body section 11, and the vibration-damping members 32 intervene between the stepped projections 28b of the vibration-damping plate 27 and the memory body section 11. In this state, the vibration-damping cover 22 and the vibration-damping plate 27 are clamped to the outer member 14, sandwiching and holding it securely. Using this construction, in addition to the fact that the vibration-damping containing case 21 has its mechanical strength increased and damping characteristics enhanced, it can damp or limit the vibration caused by the high-speed operation of the memory body section 11, by the vibration-damping members 31 and 32.

Moreover, between the vibration-damping cover 22 and the memory body section 11, the vibration-damping members 33 intervene between the stepped projections 24b and the male screws 37 that fasten them to the outer member 14. Similarly, the vibration-damping members 34 and 35 intervene between the vibration-damping plate 27 and the housing 91 of the electronic apparatus, which are screwed together by the male screws 38. By using this construction, the vibration-damping containing case 21 can avoid vibration caused by the male screws 37 and 38 directly contacting the vibration-damping cover 22 and the vibration-damping plate 27, being directly transmitted between the memory body section 11 and the housing 91 of the electronic apparatus. Furthermore, it is also possible to damp and limit small vibrations transmitted between the vibration-damping plate 27 and the housing 91 of the electronic apparatus.

In this manner, according to this exemplary embodiment, the stepped projections 23b, 24b, and 28b are formed on the vibration-damping cover 22 and the vibration-damping plate 27 of the vibration-damping containing case 21 to increase the mechanical stiffness, and the memory body section 11, which is a source of vibration and noise, is sandwiched or screwed securely via the vibration-damping members 31 to 35. By using this construction, the memory body section 11 is held in a condition whereby it is totally covered using a simple construction, so that noise can be isolated, and also the transmission of vibrations can be suppressed. Consequently, it is possible to improve the damping and sound insulation of the memory device 10 using a simple construction, so that it is possible to realize a small-sized electronic device with excellent low noise characteristics. As a result, it is possible to provide a very silent memory device 10 that can suppress noise caused by the memory body section 11 and can also limit the transmission of vibrations, and an electronic apparatus such as a personal computer in which it is installed.

### Example 1

As example 1, a vibration-damping containing case 21 containing a hard disc drive as a memory body section 11 was formed with the following sizing to produce a shielded memory device 10. FIG. 7 shows the results obtained by measuring the noise in the case where the shielded memory device 10 was assembled and mounted in different types of personal computer.

For the vibration-damping containing case 21, a steel plate with a thickness of 1.6 mm was processed to fabricate a vibration-damping cover 22 and a vibration-damping plate 27, and the vibration-damping containing case 21 was formed as a box 220 mm in length, 140 mm in width, and 50 mm in height. Stepped projections 23b were formed in the top face part 22a of the vibration-damping cover 22 with a difference in level of 1.5 mm by drawing, and stepped projections 24b were formed in the side face parts 22b with a difference in level of 1.5 mm by drawing. Stepped projections 28b were also formed in the vibration-damping plate 27 with a difference in level of 1.5 mm by drawing. Vibration-damping members 31 and 32 that intervene between the vibration-damping cover 22, the vibration-damping plate 27, and the memory body section 11, were formed from a rubber type material with a thickness of 1.5 mm.

Vibration-damping members 33 that intervene over the male screws 36 clamping the vibration-damping cover 22 and the memory body section 11 securely, and vibration-damping members 34 and 35 that intervene over the male screws 38 clamping the vibration-damping plate 27 and the housing 91 of the personal computer securely were formed from a urethane type material with a total thickness of 6 mm.

In both the case of a personal computer in which this memory device 10 was installed, and the case of a personal computer in which a conventional memory device was installed with a memory body section 11 simply contained in and screw fastened to a vibration-damping containing case, the noise generated in a situation where the memory body section 11 was operated at high speed and reading and writing were performed, was measured in a fully anechoic chamber. From this, as shown in FIG. 7, in the case of the conventional memory device, the noise values were 23 dB (device front face) and 24 dB (device back face) in a personal computer type A, and 26 dB (device front face) and 27 dB (device back face) in a personal computer type B. In contrast, in the case of the memory device 10, they were 21 dB (device front face) and 22 dB (device back face) in a personal computer type A, and were 23 dB (device front face) and 24 dB (device back face) in a personal computer type B. Therefore, compared with the conventional memory device, in the case where the memory device 10 was used, the noise value was able to be attenuated by approximately 2 to 3 dB. From this it is seen that the silence of the memory device 10 was improved markedly.

### Exemplary Embodiment 2

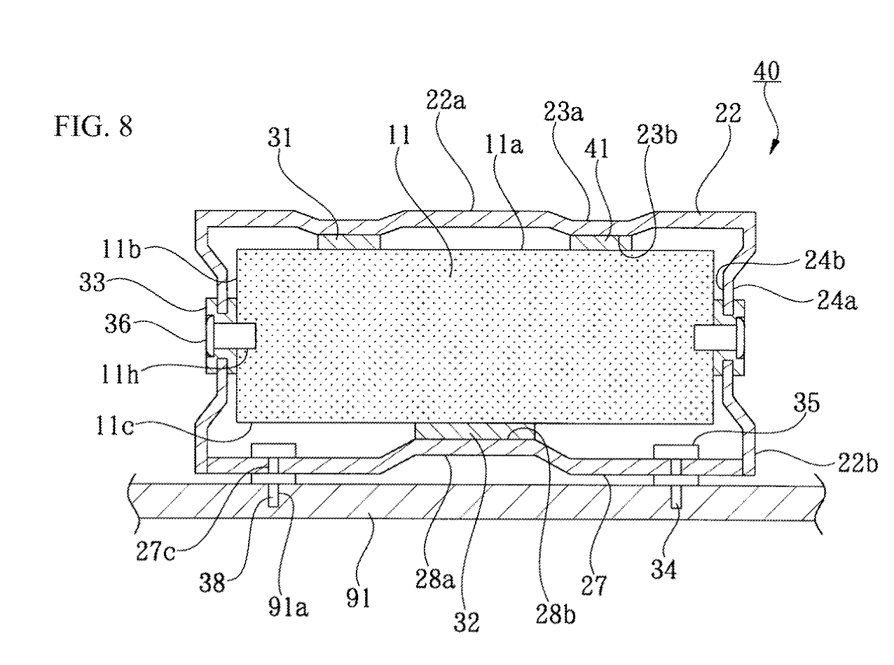

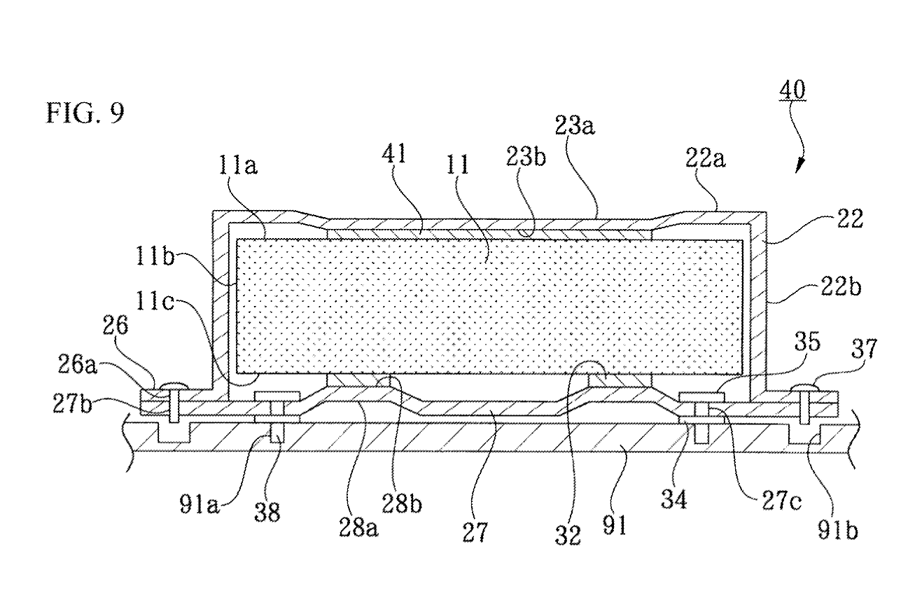

Next, FIG. 8 is a cross-sectional view corresponding to line A-A of FIG. 1, and shows the structure of a vibration-damping containing case for an electronic device of a second exemplary embodiment of this invention. FIG. 9 is a cross-sectional view corresponding to line B-B of FIG. 1, and shows the structure of the vibration-damping containing case for the electronic device shown in FIG. 8. Since the construction of the second exemplary embodiment is almost the same as the first exemplary embodiment, the same reference symbols are used for the same elements to describe the characteristic parts (the same applies in the other exemplary embodiments described hereunder).

As shown in FIG. 8 and FIG. 9, in a memory device 40, instead of adhering one of the vibration-damping members 31 to the stepped projection 23b of the vibration-damping cover 22 of the vibration-damping containing case 21 in which the memory body section 11 is contained, a heat conducting member 41 is adhered to the stepped projection 23b of the vibration-damping cover 22. The heat conducting member 41 is fabricated from, for example, a heat conducting material that has excellent heat transfer properties, such as silicon resin, or a carbon-based or conductive resin. In addition to replacing only the vibration-damping member 31 by the heat conducting member 41, the other vibration-damping members 32 to 35 may also be replaced by the heat conducting member 41. Furthermore, in the case where the heat conducting member 41 has not only heat transfer characteristics but also damping characteristics, the heat conducting member 41 may also be substituted for the vibration-damping members.

Therefore, in the memory device 40, heat generated by the high-speed rotation of the medium 12 of the memory body section 11, and the high-speed operation of the arm 13 can be transmitted to the vibration-damping cover 22 made from metal in order to cool them. Hence it is possible to prevent an increase in temperature, which becomes a factor in failure of the memory body section 11.

In this manner, according to this exemplary embodiment, in addition to the effects obtained in the above-described first exemplary embodiment, an effect can be obtained in which the body section 11 can be cooled effectively. Consequently, thermal factors do not prevent the memory device 40 from being small sized, so that it is possible to provide a small sized memory device 40 having excellent low noise characteristics and an electronic apparatus such as a personal computer in which this is installed.

### Exemplary Embodiment 3

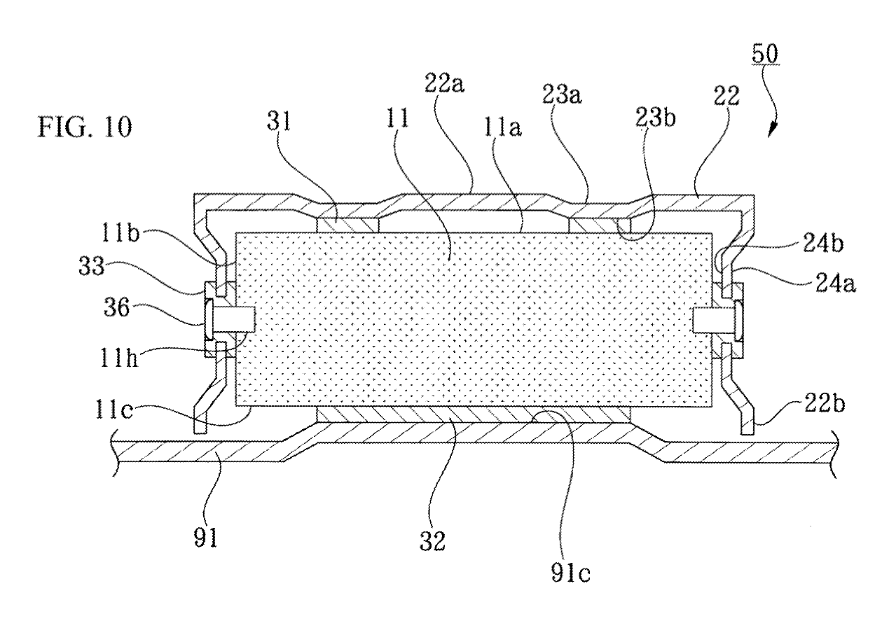

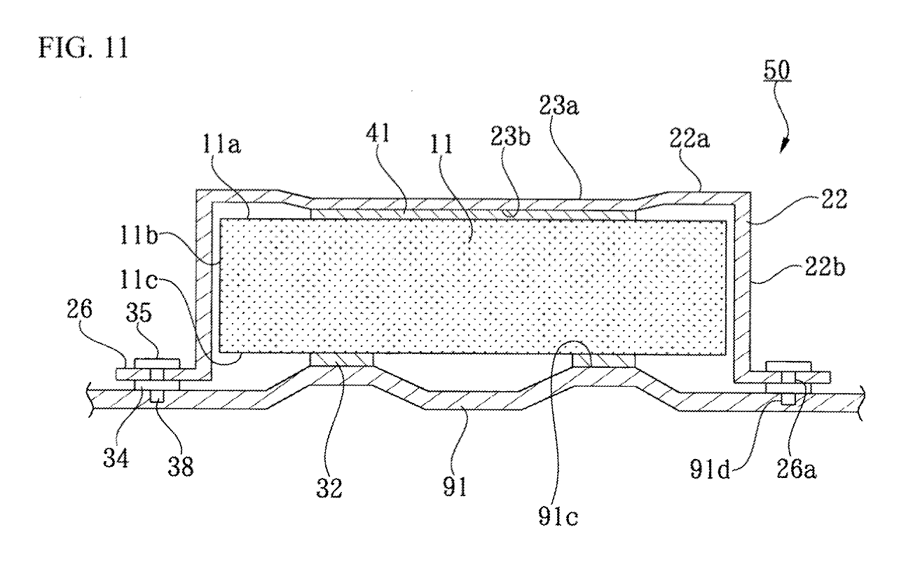

FIG. 10 is a cross-sectional view corresponding to line A-A of FIG. 1, and shows the structure of a vibration-damping containing case for an electronic device of a third exemplary embodiment of this invention. FIG. 11 is a cross-sectional view corresponding to line B-B of FIG. 1, and shows the structure of the vibration-damping containing case for the electronic device shown in FIG. 10.

As shown in FIG. 10 and FIG. 11, in a memory device 50, the vibration-damping plate 27 is omitted, and stepped projections 91c, which are the same shape as the stepped projections 28b, are provided in the housing 91 of the electronic apparatus. The stepped projections 91c are formed by oblong or circular drawing. Vibration-damping members 32 are adhered to the stepped projections 91c. In the vibration-damping cover 22, instead of the male screws 37, male screws 38 pass through the screw holes 26a of the flange parts 26. In addition, female threads 91d into which the male screws 38 are screwed are formed in corresponding locations of the housing 91, and the vibration-damping cover 22 is clamped to the housing 91 securely. The flange parts 26 of the vibration-damping cover 22 are screwed to the housing 91 so as to be clamped by the tightening force of the male screws 38 screwed into the female threads 91d of the housing 91 of the electronic apparatus via intervening vibration-damping members 34 and 35, similarly to the case where the vibration-damping plate 27 is used.

In this manner, according to this exemplary embodiment, even if the vibration-damping plate 27 of the above-described first exemplary embodiment is omitted, it is possible to build a memory device 50 with a similar construction, so that the same effects can be obtained. Consequently, it is possible to produce a memory device 50 that ensures excellent damping and sound insulation at low cost using a simple construction in which the part count is further decreased, so that it is possible to provide a highly silent memory device 50 and an electronic apparatus such as a personal computer in which it is installed.

### Exemplary Embodiment 4

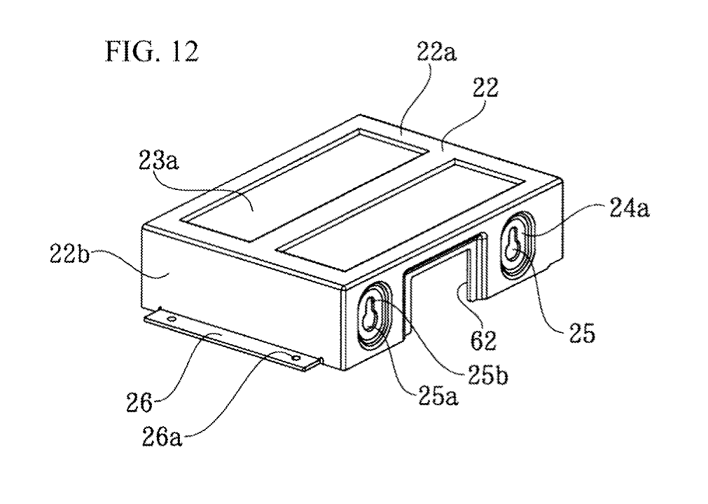

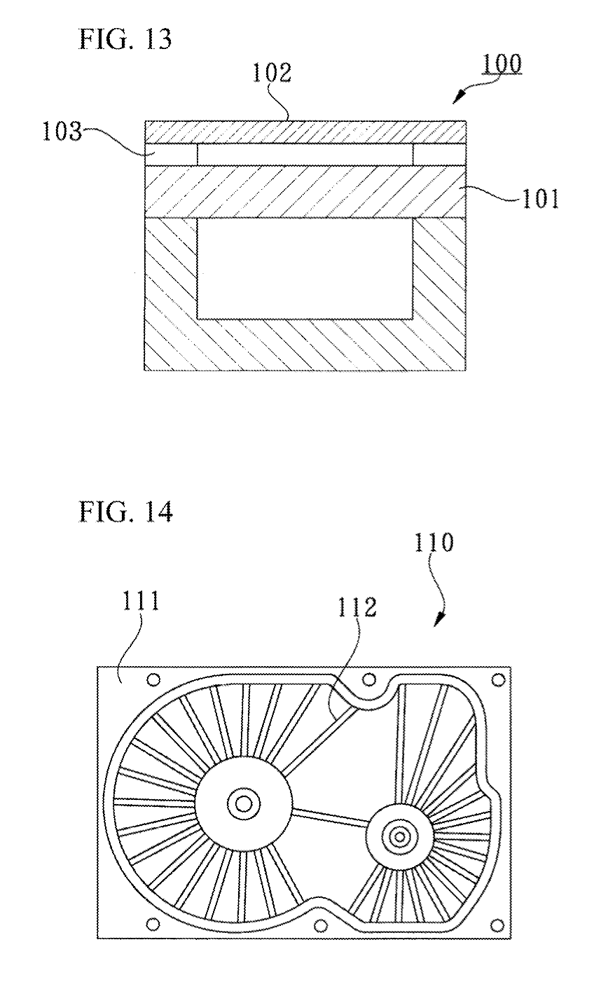

FIG. 12 is a perspective view showing the appearance of the structure of a vibration-damping containing case for an electronic device of a fourth exemplary embodiment of this invention.

As shown in FIG. 12, notch sections 62 are formed between the concave parts 24a (stepped projections 24b) of the side face parts 22b in the vibration-damping cover 22 of the memory device 10. It is possible to grasp the side faces 11b of the memory body section 11 to be contained in the vibration-damping containing case 21 from the notch sections 62. The notch sections 62 may be formed in the short sides of the side face parts 22b of the vibration-damping cover 22 instead of being formed in the long sides of the side face parts 22b of the vibration-damping cover 22.

In this manner, according to this exemplary embodiment, in addition to the effects of the above-described first exemplary embodiment, an effect can be obtained in which the position of the memory body section 11 can be finely adjusted easily while being temporarily secured during assembly of a memory device 60. Therefore it is possible to avoid vibration occurring due to the parts making contact with each other because of a slight displacement of the parts. For example, it is possible to assemble the memory device 10 accurately and easily by making adjustments such that the screw parts 38b of the male screws 38 that are screwed securely to the housing 91 of the electronic apparatus do not touch the vibration-damping plate 27 directly. Furthermore, even in the case where the memory body section 11 fails, it is possible to exchange it easily and reassemble it, improving the integrity. The vibration-damping cover 22 in which the notch sections 62 are formed may be used in the other exemplary embodiments described above.

As above, one exemplary embodiment of this invention has been described with reference to the drawings. However, specific constructions are not limited to the exemplary embodiment. Any design change and the like within a scope that does not depart from the gist of the present invention is included in the present invention. For example, this invention can also be adopted for compact disk reading and writing devices.

This application is based on and claims the benefit of priority from Japanese Patent Application No. 2009-020946, filed Jan. 30, 2009, the disclosure of which is incorporated herein in its entirety by reference.

### INDUSTRIAL APPLICABILITY

This invention can be used widely, not only for a memory device for a personal computer, but also for other electronic devices that become vibration sources. For example, it can also be used for a device for recording video images, or the like.

### REFERENCE SYMBOLS

10, 40, 50 Shielded memory device (Electronic device)
11 Memory body section (Vibration source)
11a Top face (Outer surface)
11b Side face (Outer surface)
11c Bottom face (Outer surface)
21 Vibration-damping containing case (Case member)
22 Vibration-damping cover
22a Top face part (Opposing face)
22b Side face part
22c Opening
23b, 28b, 91c Stepped projection (Clamped convex part)
24b Stepped projection (Screwed convex part)
27 Vibration-damping plate (Opposing face)
31 to 35 Vibration-damping member
41 Heat-conducting member
62 Notch section
91 Housing

1. A vibration-damping containing case for an electronic device, comprising
a stepped projection which is provided on an inner surface of a case member containing an electronic device which becomes a vibration source in a state of covering an outer surface of the electronic device, and which holds the outer surface of the electronic device in a state of sandwiching the outer surface of the electronic device,
the stepped projection holding the outer surface of the electronic device via a vibration-damping member.

2. The vibration-damping containing case for an electronic device according to claim 1, wherein the stepped projection is formed so as to extend in a crosswise direction or a lengthwise direction of the case member.

3. The vibration-damping containing case for an electronic device according to claim 1, wherein a plurality of the stepped projections are formed on at least each of opposing surfaces facing each other among inner surfaces of the case facing the outer surface of the electronic device, so as to parallel to each other.

4. The vibration-damping containing case for an electronic device according to claim 3, wherein the stepped projections are formed so as to face each other in a perpendicular orientation to each other.

5. The vibration-damping containing case for an electronic device according to claim 1, wherein the stepped projection is formed such that an outer surface of the case member is formed in a concave shape, and the inner surface of the case member is formed in a convex shape.

6. The vibration-damping containing case for an electronic device according to claim 1, wherein:
a plurality of the stepped projections include a clamped convex part formed in a size to clamp an outer surface of the electronic device, and a screwed convex part that is screwed to an outer surface of the electronic device; and
a plurality of the vibration-damping members include a vibration-damping member that is adhered to the clamped convex part and is interposed in a clamped state between the clamped convex part and an outer surface of the electronic device, and a vibration-damping member that is interposed in a clamped state between the screwed convex part and an outer surface of the electronic device by tightening a screw member.

7. The vibration-damping containing case for an electronic device according to claim 6, wherein:
the case member includes a vibration-damping cover that covers the electronic device such that an opening of the electronic device is open, and so as to face an outer surface of the electronic device other than a bottom face, and a vibration-damping plate that faces the bottom face of the electronic device and supports it, and closes the opening;
the clamped convex part is formed on the vibration-damping plate and on an inner surface of the vibration-damping cover that faces the vibration-damping plate; and
the screwed convex part is formed on a side face of the vibration-damping cover.

8. The vibration-damping containing case for an electronic device according to claim 7, wherein the vibration-damping plate of the case member is constituted by a housing on a side of an electronic apparatus on which the electronic device is mounted.

9. The vibration-damping containing case for an electronic device according to claim 7, wherein the case member closes off the opening by screw fastening the vibration-damping plate to the vibration-damping cover, and
another vibration-damping member is provided at a screw fastening location of the vibration-damping cover and the vibration-damping plate, and is interposed in a clamped state between the vibration-damping cover and the vibration-damping plate.

10. The vibration-damping containing case for an electronic device according to claim 7, wherein the case member is formed with a notch section that opens a part of the vibration-damping cover that faces a side face of the electronic device.

11. The vibration-damping containing case for an electronic device according to claim 1, further comprising:
a heat conducting member that is intervened between the stepped projection of the case member and an outer surface of the electronic device, and conducts heat between the casing member and the electronic device.

12. An electronic device contained in a vibration-damping containing case so as to cover an outer surface,
wherein a stepped projection which holds the outer surface with the outer surface sandwiched, is formed on an inner surface of the vibration-damping containing case, and
the stepped projection holds the outer surface via a vibration-damping member.

13. The electronic device according to claim 12, wherein:
a plurality of the stepped projections include a clamped convex part formed in a size to clamp the outer surface, and a screwed convex part that is screwed to the outer surface; and
a plurality of the vibration-damping members include a vibration-damping member that is adhered to the clamped convex part and is interposed in a clamped state between the clamped convex part and the outer surface, and a vibration-damping member that is interposed in a clamped state between the screwed convex part and the outer surface by tightening a screw member.

14. The electronic device according to claim 13, wherein:
the vibration-damping containing case includes a vibration-damping cover with an opening that is open so as to cover the outer surface other than a bottom face, and a vibration-damping plate that faces the bottom face of the outer surface and supports it, and closes the opening;
the clamped convex part is formed on the vibration-damping plate and on an inner surface of the vibration-damping cover that faces the vibration-damping plate; and
the screwed convex part is formed on a side face of the vibration-damping cover.

15. The electronic device according to claim 14, wherein the vibration-damping plate of the vibration-damping containing case is constituted by a housing on a side of an electronic apparatus on which it is mounted.

16. The electronic device according to claim 14, wherein
the vibration-damping containing case closes off the opening by screw fastening the vibration-damping plate to the vibration-damping cover; and
another vibration-damping member is provided at a screw fastening location of the vibration-damping cover and the vibration-damping plate, and is interposed in a clamped state between the vibration-damping cover and the vibration-damping plate.

17. The electronic device according to claim 16, wherein the vibration-damping containing case screw fastens the vibration-damping plate by flanges formed on side edges of the vibration-damping cover.

18. The electronic device according to claim 14, wherein the vibration-damping containing case is formed with a notch section that opens a part of a side face of the vibration-damping cover.

19. The electronic device according to claim 12, wherein the vibration-damping containing case further includes a heat conducting member that is intervened between the stepped projection and the outer surface, and conducts heat between the vibration-damping containing case and the electronic device.

20. (canceled)

21. An electronic apparatus with an electronic device contained in a vibration-damping containing case according to claim 1, and mounted with a vibration-damping member that prevents transmission of vibration, intervened between the electronic device and a housing.
